(19) United States
(12) Patent Application Publication
(10) Pub. No.: US 2024/0318307 A1
(43) Pub. Date: Sep. 26, 2024

(54) SUBSTRATE PROCESSING DEVICE

(71) Applicant: Samsung Electronics Co., Ltd., Suwon-si (KR)

(72) Inventors: Byunghwan Kong, Suwon-si (KR); Heesun Song, Suwon-si (KR); Seongwan Kim, Suwon-si (KR); Heeyeon Kim, Suwon-si (KR); Seongho Park, Suwon-si (KR); Hyunho Choi, Suwon-si (KR)

(21) Appl. No.: 18/611,936

(22) Filed: Mar. 21, 2024

(30) Foreign Application Priority Data
Mar. 24, 2023 (KR) 10-2023-0039215
Apr. 13, 2023 (KR) 10-2023-0048986

(51) Int. Cl. C23C 16/44

(52) U.S. Cl. CPC C23C 16/4412; H01L 21/67017

(57) ABSTRACT

Provided is a substrate processing device including a first tube configured to load a substrate in an interior space thereof, a second tube configured to include the first tube therein, and a process gas supply line configured to inject process gas to the interior space of the first tube, wherein the first tube has a plurality of exhaust holes penetrating a sidewall of the first tube, the plurality of exhaust holes include a main exhaust hole and a multi-exhaust hole region disposed in a line in the vertical direction, the multi-exhaust hole region includes a plurality of auxiliary exhaust holes, and the height of each of the plurality of auxiliary exhaust holes is less than the height of the main exhaust hole.

### CROSS-REFERENCE TO RELATED APPLICATION

This application is based on and claims priority under 35 U.S.C. § 119 to Korean Patent Application Nos. 10-2023-0039215, filed on Mar. 24, 2023, and 10-2023-0048986, filed on Apr. 13, 2023, in the Korean Intellectual Property Office, the disclosures of which are incorporated by reference herein in their entireties.

### BACKGROUND

Aspects of the inventive concept relate to a substrate processing device, and more particularly, to a vertical furnace-type substrate processing device.

A processing device capable of performing various processes may be used for semiconductor device manufacturing. For example, a vertical-type semiconductor processing device capable of simultaneously performing a process on a plurality of substrates or the like may be used. This vertical-type semiconductor processing device is called a vertical furnace. A generally used vertical-type semiconductor processing device simultaneously performs a process on several to hundreds of wafers or the like stacked therein. Gas may be sprayed inside a semiconductor processing device with stacked wafers or the like. The gas may be sprayed by a nozzle or the like. The sprayed gas may be applied to wafers or the like to perform various processes. Processes performed inside a semiconductor processing device may include an atomic layer deposition (ALD) process, a chemical vapor deposition (CVD) process, and the like.

### SUMMARY

Aspects of the inventive concept provide a substrate processing device for manufacturing a semiconductor device having a high aspect ratio.

Aspects of the inventive concept also provide a substrate processing device with no difference in deposition thickness among a plurality of substrates when a process is simultaneously performed on the plurality of substrates.

In addition, the problems to be solved by the technical idea of the inventive concept are not limited to the problems mentioned above, and the other problems could be clearly understood by those of ordinary skill in the art from the description below.

According to an aspect of the inventive concept, there is provided a substrate processing device including a first tube configured to load a substrate in an interior space thereof, a second tube configured to include the first tube therein, and a process gas supply line configured to inject process gas to the interior space of the first tube, wherein the first tube has a plurality of exhaust holes penetrating a sidewall of the first tube, the plurality of exhaust holes include a main exhaust hole and a multi-exhaust hole region disposed in a line in the vertical direction, the multi-exhaust hole region includes a plurality of auxiliary exhaust holes, and the height of each of the plurality of auxiliary exhaust holes is less than the height of the main exhaust hole.

According to another aspect of the inventive concept, there is provided a substrate processing device including a first tube configured to load a substrate in an interior space thereof, a second tube configured to include the first tube therein, and a process gas supply line configured to inject process gas to the interior space of the first tube, wherein the first tube has a plurality of exhaust holes penetrating a sidewall of the first tube, the plurality of exhaust holes include a main exhaust hole and a multi-exhaust hole region, the multi-exhaust hole region includes a plurality of auxiliary exhaust holes, the main exhaust hole extends in the vertical direction after passing through an intermediate point of the height of the first tube, and the horizontal width of at least a portion of the main exhaust hole is different from at least one of the horizontal width of a lower surface of the main exhaust hole and the horizontal width of an upper surface of the main exhaust hole.

According to another aspect of the inventive concept, there is provided a substrate processing device including a first tube configured to load a substrate in an interior space thereof, a second tube configured to include the first tube therein and having a through hole in a sidewall thereof, a process gas supply line configured to inject process gas to the interior space of the first tube, and an exhaust port connected to the through hole of the second tube and configured to discharge the process gas to the outside, wherein the first tube has a plurality of exhaust holes penetrating a sidewall of the first tube, the plurality of exhaust holes include a main exhaust hole and a multi-exhaust hole region, the main exhaust hole extends in the vertical direction with a variable horizontal width, the multi-exhaust hole region includes a plurality of auxiliary exhaust holes, and at least some of the plurality of auxiliary exhaust holes face the exhaust port.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view schematically illustrating a substrate processing device according to some embodiments;

FIG. 2 is a top view schematically illustrating the substrate processing device of FIG. 1;

FIG. 3 is a perspective view schematically illustrating a portion of the substrate processing device of FIG. 1;

FIG. 4 is a front view schematically illustrating a part of the substrate processing device of FIG. 1;

FIG. 5 is a graph showing respective deposition thicknesses of a plurality of substrates deposited by a substrate processing device according to some embodiments;

FIGS. 6 to 8 are front views schematically illustrating first tubes of a substrate processing device, according to an embodiment;

FIGS. 9 and 10 are front views schematically illustrating first tubes of a substrate processing device, according to an embodiment;

FIGS. 11 to 13 are front views schematically illustrating first tubes of a substrate processing device, according to an embodiment;

FIGS. 14 to 16 are front views schematically illustrating first tubes of a substrate processing device, according to an embodiment;

FIG. 17 is a top view schematically illustrating a substrate processing device according to some embodiments;

FIG. 18 is a perspective view schematically illustrating a portion of the substrate processing device of FIG. 17; and

FIGS. 19 and 20 are front views schematically illustrating a first tube of the substrate processing device of FIG. 17.

### DETAILED DESCRIPTION OF THE EMBODIMENTS

The embodiments may be variously modified and have various forms, and some embodiments are illustrated in the drawings and described in detail. However, it is not intended to limit the embodiments to a particular disclosure form.

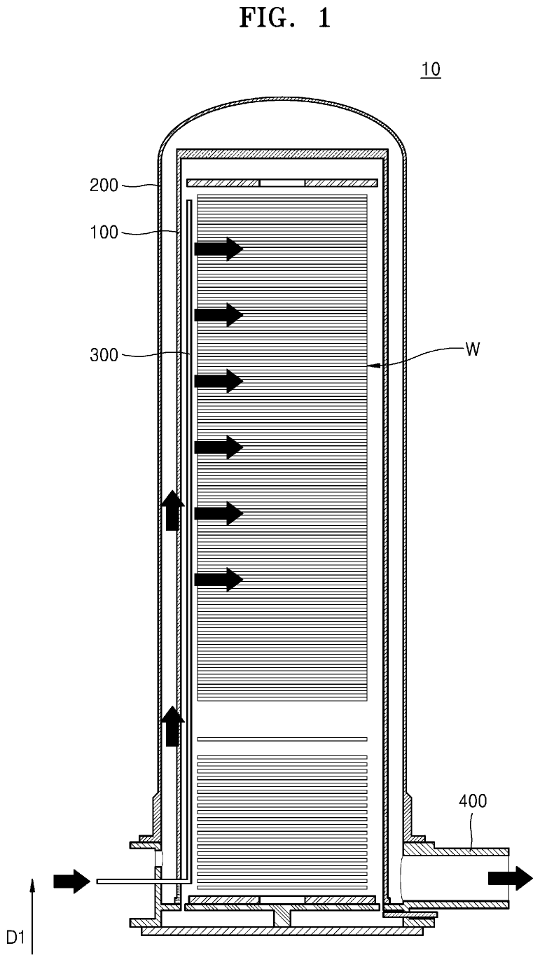

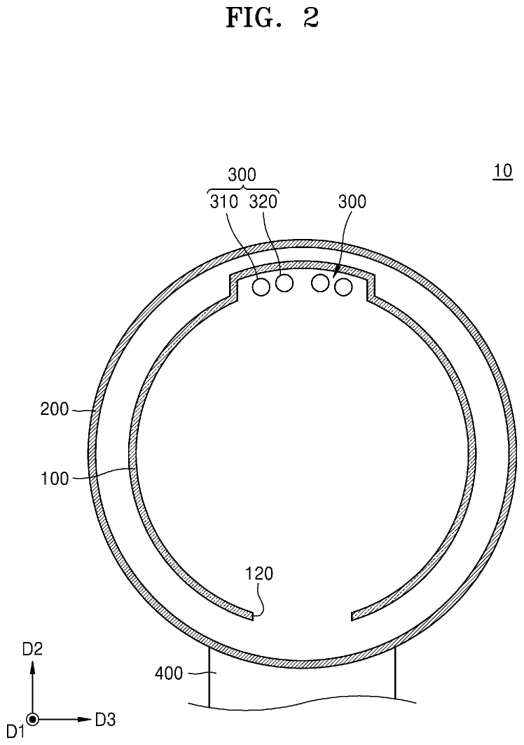

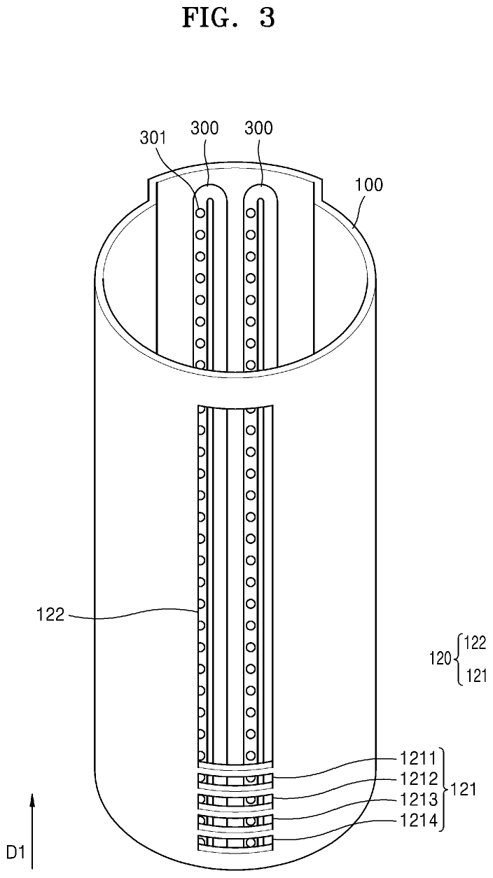

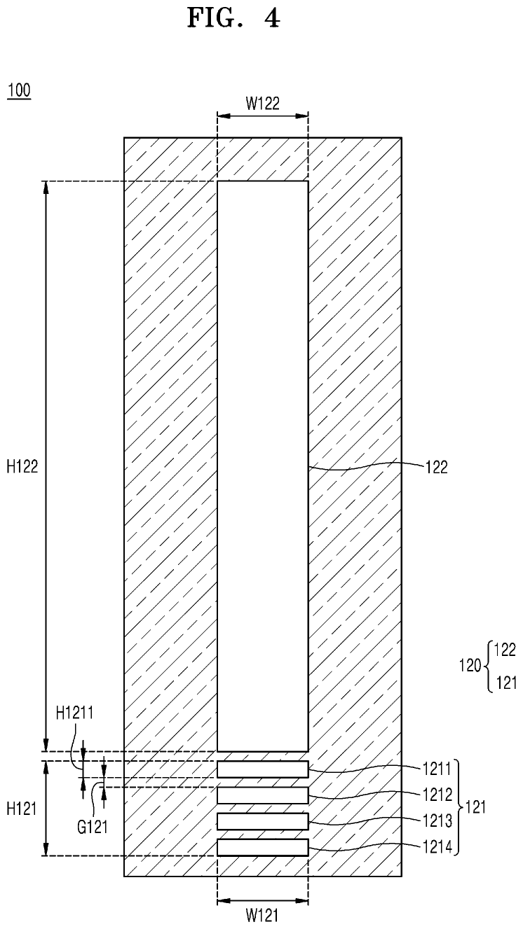

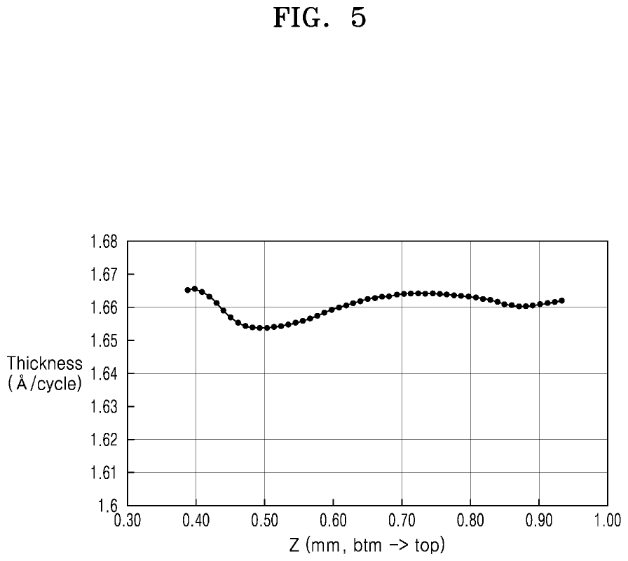

FIG. 1 is a cross-sectional view schematically illustrating a substrate processing device 10 according to some embodiments. FIG. 2 is a top view schematically illustrating the substrate processing device 10 of FIG. 1. FIG. 3 is a perspective view schematically illustrating a portion of the substrate processing device 10 of FIG. 1. FIG. 4 is a front view schematically illustrating a part of the substrate processing device 10 of FIG. 1. FIG. 5 is a graph showing respective deposition thicknesses of a plurality of substrates deposited by a substrate processing device according to some embodiments.

Referring to FIGS. 1 to 5, the substrate processing device 10 may include a first tube 100, a second tube 200, a process gas supply line 300, and an exhaust port 400.

The first tube 100 may include an interior space. For example, the first tube 100 may have a cylindrical shape extending in a first direction D1. The first tube 100 may be an inner tube of the substrate processing device 10.

The first tube 100 may load a plurality of substrates W in the interior space thereof. The plurality of substrates W may be loaded inside the first tube 100 and be spaced apart from each other in the first direction D1. In some embodiments, a deposition process may be simultaneously performed on the plurality of substrates W by process gas injected to the interior space of the first tube 100.

Hereinafter, a second direction D2 and a third direction D3 intersecting with the first direction D1 may be defined and the second direction D2 may intersect with the third direction D3. For example, the first direction D1 may be perpendicular to the second direction D2 and the third direction D3, and the second direction D2 may be perpendicular to the third direction D3.

The first tube 100 may include a plurality of exhaust holes 120. The plurality of exhaust holes 120 may be holes through which the process gas injected to the inside of the first tube 100 is exhausted. For example, the first tube 100 may include the plurality of exhaust holes 120 disposed in the first direction D1. The plurality of exhaust holes 120 may penetrate a sidewall of the first tube 100.

In some embodiments, the plurality of exhaust holes 120 may face the process gas supply line 300 to be described below. For example, the plurality of exhaust holes 120 may be spaced apart from the process gas supply line 300 in a direction parallel to the second direction D2.

The plurality of exhaust holes 120 may include a main exhaust hole 122 and a multi-exhaust hole region 121. The multi-exhaust hole region 121 may include a plurality of mini (e.g., auxiliary) exhaust holes. The main exhaust hole 122 and the multi-exhaust hole region 121 may be disposed in a line in the first direction D1. In some embodiments, the multi-exhaust hole region 121 may be under the main exhaust hole 122 in the vertical direction (e.g., the first direction D1).

The plurality of mini exhaust holes may be spaced apart from each other in the first direction D1. In some embodiments the multi-exhaust hole region 121 may include first to fourth mini exhaust holes 1211, 1212, 1213, and 1214. However, the number of mini exhaust holes in the multi-exhaust hole region 121 is not limited thereto.

The first to fourth mini exhaust holes 1211, 1212, 1213, and 1214 may be spaced apart from each other in the first direction D1. Two adjacent mini exhaust holes among the first to fourth mini exhaust holes 1211, 1212, 1213, and 1214 may be spaced apart from each other by a first distance G121 in the first direction D1. The first distance G121 may be about 2 mm to about 5 mm. For example, the spaced distance between the first mini exhaust hole 1211 and the second mini exhaust hole 1212 in the first direction D1 may be the first distance G121. Although FIG. 4 shows that the plurality of mini exhaust holes are spaced apart from each other by the same distance, the plurality of mini exhaust holes are not limited thereto and may be spaced apart from each other by different distances.

The horizontal width of each of the first to fourth mini exhaust holes 1211, 1212, 1213, and 1214 may be greater than the height of each of the first to fourth mini exhaust holes 1211, 1212, 1213, and 1214. For example, when the horizontal width (circumferential direction length) of the first mini exhaust hole 1211 is a first width W121 and the height (length in the first direction D1) of the first mini exhaust hole 1211 is a first height H1211, the first width W121 may be greater than the first height H1211. In some embodiments, the first width W121 may be about 10 mm to about 20 mm and the first height H1211 may be about 5 mm to about 10 mm.

In some embodiments, when the horizontal widths of the plurality of mini exhaust holes are the same as the first width W121, the horizontal width of the multi-exhaust hole region 121 may be the first width W121. When the horizontal widths of the plurality of mini exhaust holes are different from each other, the horizontal width of the multi-exhaust hole region 121 may be the horizontal width of a mini exhaust hole having the greatest horizontal width among the plurality of mini exhaust holes.

Although the first mini exhaust hole 1211 has been described, the size (the horizontal width and the height) of each of the second to fourth mini exhaust holes 1212, 1213, and 1214 may be substantially the same as the size of the first mini exhaust hole 1211. However, the first to fourth mini exhaust holes 1211, 1212, 1213, and 1214 are not limited thereto and the sizes of some or all of the first to fourth mini exhaust holes 1211, 1212, 1213, and 1214 may be different from each other.

In some embodiments, the multi-exhaust hole region 121 may include five mini exhaust holes having a horizontal width of about 15 mm and a height of about 7 mm, wherein each of the five mini exhaust holes may be spaced apart by about 3 mm from an adjacent mini exhaust hole in the vertical direction. However, the size of each of the plurality of mini exhaust holes of the multi-exhaust hole region 121 and the spaced distance between two adjacent ones of the plurality of mini exhaust holes are not limited thereto.

In some embodiments, the horizontal width of the multi-exhaust hole region 121 may be substantially the same as the horizontal width of the main exhaust hole 122. For example, the horizontal widths of the plurality of mini exhaust holes of the multi-exhaust hole region 121 may be the same as the first width W121 and the horizontal width of the main exhaust hole 122 may have a constant value of a second width W122. Herein, the first width W121 may be substantially the same as the second width W122.

A height H1211 of each of the plurality of mini exhaust holes of the multi-exhaust hole region 121 may be different from a height H122 of the main exhaust hole 122. The height H1211 of each of the plurality of mini exhaust holes may be less than the height H122 of the main exhaust hole 122. A height H121 of the multi-exhaust hole region 121 may be less than the height H122 of the main exhaust hole 122. In some embodiments, the height H122 of the main exhaust hole 122 may be about 3 times to about 15 times the height H121 of the multi-exhaust hole region 121. For example, when viewing in the second direction D2, the main exhaust hole 122 and the multi-exhaust hole region 121 may have different areas.

The second tube 200 may include an interior space. For example, the second tube 200 may have a cylindrical shape extending in the first direction D1. For example, the first direction D1 may be the vertical direction. The second tube 200 may surround the first tube 100. For example, the first tube 100 may be in the interior space of the second tube 200. The second tube 200 may include the first tube 100 therein. The second tube 200 may be an outer tube of the substrate processing device 10.

The process gas supply line 300 may be inside the first tube 100. The process gas supply line 300 may extend in the first direction D1. The process gas supply line 300 may include a plurality of process holes 301 disposed in the first direction D1. The plurality of process holes 301 may penetrate a sidewall of the process gas supply line 300. The number and shape of process gas supply lines 300 are not limited to the drawings and description.

In some embodiments, each of the process gas supply lines 300 may have an inverted U shape. Each of the process gas supply lines 300 may include a first portion 310 and a second portion 320. The first portion 310 and the second portion 320 of the process gas supply line 300 may extend in the first direction D1 to be parallel to each other. The top of the first portion 310 of the process gas supply line 300 may be connected to the top of the second portion 320.

Through the process gas supply line 300, the process gas may be injected to the interior space of the first tube 100. For example, through the plurality of process holes 301 formed in the sidewall of the process gas supply line 300, the process gas may be injected to the interior space of the first tube 100. In some embodiments, among the plurality of process holes 301 of the process gas supply line 300, the process gas may be first injected through a process hole 301 at a relatively lower vertical level of the first tube 100 than a process hole 301 at a relatively higher vertical level of the first tube 100. Accordingly, the process gas injected through the process gas supply line 300 may have a speed at a lower vertical level of the first tube 100 that is greater than the speed at a higher vertical level of the first tube 100. In some embodiments, among the plurality of process holes 301 of the process gas supply line 300, the process gas may be first injected through a process hole 301 at a relatively higher vertical level of the first tube 100 than a process hole 301 at a relatively lower vertical level of the first tube 100. Accordingly, the process gas injected through the process gas supply line 300 may have a speed at a higher vertical level of the first tube 100 that is greater than the speed at a lower vertical level of the first tube 100.

The exhaust port 400 may discharge the process gas inside the second tube 200 to the outside. The exhaust port 400 may be connected to a sidewall of the second tube 200 to discharge the process gas inside the second tube 200 to the outside. For example, the second tube 200 may have a hole penetrating the sidewall thereof and an inlet of the exhaust port 400 may be connected to the hole so that the exhaust port 400 discharges the process gas inside the second tube 200 to the outside. In some embodiments, the exhaust port 400 may form negative pressure therein by a pump to move air so that the process gas moves from the inside of the second tube 200 to the exhaust port 400.

In some embodiments, the exhaust port 400 may be connected to a lower portion of the second tube 200. For example, the exhaust port 400 may be on a floor on which the substrate processing device 10 is provided. The exhaust port 400 may face the plurality of exhaust holes 120. In some embodiments, the exhaust port 400 may be at an opposite side to the process gas supply line 300. For example, the exhaust port 400 may be spaced apart from the process gas supply line 300 with the plurality of exhaust holes 120 of the first tube 100 therebetween. The exhaust port 400 may be spaced apart from the process gas supply line 300 in a direction parallel to the second direction D2. For example, the exhaust port 400, the plurality of exhaust holes 120, and the process gas supply line 300 may be positioned in a line in the second direction D2. In some embodiments, the vertical level of the exhaust port 400 may be substantially the same as the vertical level of the multi-exhaust hole region 121. For example, a spaced distance between the exhaust port 400 and a lower surface of the second tube 200 may be substantially the same as a spaced distance between the center point of the multi-exhaust hole region 121 and a lower surface of the first tube 100. The inlet of the exhaust port 400 may face the multi-exhaust hole region 121. Accordingly, the process gas in the vicinity of the multi-exhaust hole region 121 facing the inlet of the exhaust port 400 may receive more influence of an external force formed by the exhaust port 400 than the process gas in the vicinity of the main exhaust hole 122.

When schematically describing movement of the process gas, the process gas may be introduced to the interior space of the first tube 100 through the process gas supply line 300, react with the plurality of substrates W loaded inside the first tube 100, and be discharged to the outside through the exhaust port 400 of the second tube 200 by passing through the plurality of exhaust holes 120 of the first tube 100.

In some embodiments, the inlet of the exhaust port 400 may have a circular shape. The diameter of the inlet of the exhaust port 400 may be about 50 mm to about 500 mm. In some embodiments, the diameter of the inlet of the exhaust port 400 may be about 200 mm. As the size of the inlet of the exhaust port 400 increases, the performance of discharging the process gas inside the first tube 100 and the second tube 200 to the outside may be improved (e.g., the rate of discharge is increased).

In some embodiments, when a deposition process is performed on the plurality of substrates W, respective deposition thicknesses to be deposited on the plurality of substrates W loaded inside the first tube 100 may increase by improving the process gas supply performance of the process gas supply line 300 and improving the process gas discharge performance of the exhaust port 400. Accordingly, an aspect ratio of devices formed on the plurality of substrates W may be improved.

In the graph of FIG. 5, the X axis indicates a vertical level of the first tube 100 (i.e., the positions at which substrates W are disposed in the first tube 100) and the Y axis indicates the deposition thickness of a substrate W loaded inside the first tube 100. For example, the graph of FIG. 5 shows respective deposition thicknesses of the plurality of substrates W loaded inside the first tube 100 in the first direction D1 according to the vertical level at which they are disposed in the first tube 100.

Referring to the graph of FIG. 5, in the substrate processing device 10 according to aspects of the inventive concept, the difference between the deposition thickness of a substrate loaded at a lower vertical level inside the first tube 100 and the deposition thickness of a substrate loaded at a higher vertical level inside the first tube 100 is not large. For example, when simultaneously performing a deposition process on the plurality of substrates W through the substrate processing device 10, the difference between deposition thicknesses of the plurality of substrates W loaded inside the first tube 100 according to vertical levels may be small. According to aspects of the inventive concept, when simultaneously performing a deposition process on the plurality of substrates W through the substrate processing device 10, the difference between deposition thicknesses of the plurality of substrates W loaded inside the first tube 100 according to vertical levels may vary by less than 0.6%.

In the substrate processing device 10 according to aspects of the inventive concept, the discharge speed of the exhaust port 400 may be adjusted by placing the multi-exhaust hole region 121 of the plurality of exhaust holes 120 to be adjacent to the exhaust port 400. For example, because the multi-exhaust hole region 121 includes the plurality of mini exhaust holes, the speed of discharging the process gas by the exhaust port 400 may decrease. Accordingly, the speed of discharging the process gas from the interior space of the first tube 100 may be substantially constant regardless of whether the process gas is adjacent to the exhaust port 400. For example, the process gas may be constantly discharged to the outside at all vertical levels of the first tube 100. Accordingly, a process reaction of the plurality of substrates W loaded inside the first tube 100 may be performed at substantially the same speed regardless of vertical levels at which the plurality of substrates W are loaded inside the first tube 100. For example, for a deposition process, deposition process gas may be discharged to the outside at a constant speed at all vertical levels of the first tube 100 so that the deposition thickness of a substrate at a relatively lower vertical level inside the first tube 100 is substantially the same as the deposition thickness of a substrate at a relatively higher vertical level inside the first tube 100.

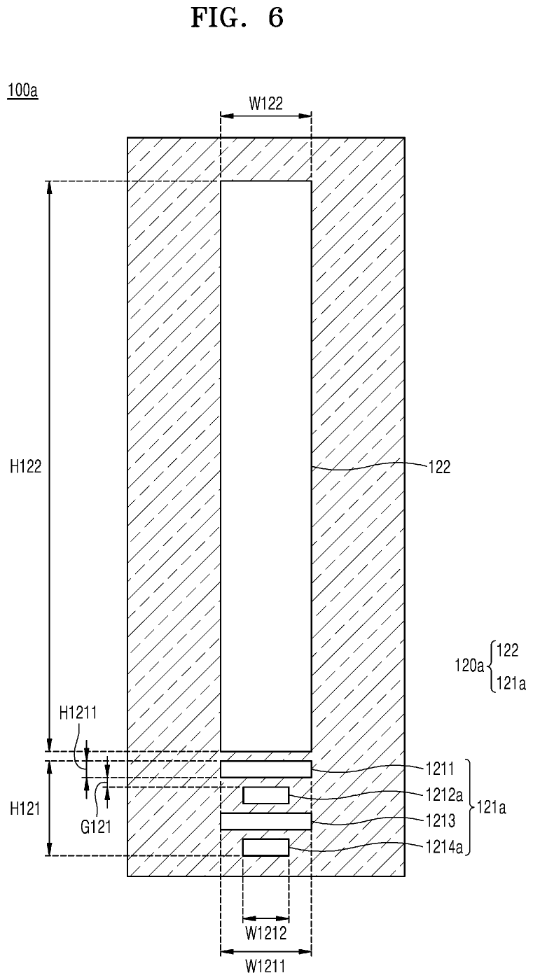

FIGS. 6 to 8 are front views schematically illustrating first tubes 100a, 100b, and 100c of a substrate processing device, according to an embodiment.

Referring to FIGS. 6 to 8, embodiments of respective pluralities of exhaust holes 120a, 120b, and 120c of the first tubes 100a, 100b, and 100c are particularly described. Hereinafter, when describing the pluralities of exhaust holes 120a, 120b, and 120c of FIGS. 6 to 8, a description made for the plurality of exhaust holes 120 of FIG. 4 is omitted and differences therefrom are described.

Referring to FIG. 6, the first tube 100a may include the plurality of exhaust holes 120a. The plurality of exhaust holes 120a may include the main exhaust hole 122 and a multi-exhaust hole region 121a. The multi-exhaust hole region 121a may include a plurality of mini exhaust holes.

The plurality of mini exhaust holes of the multi-exhaust hole region 121a may have different sizes. In other words, the plurality of mini exhaust holes may have different horizontal widths and heights. When producing the first tube 100a, the size of each of the plurality of mini exhaust holes may be designed in advance through a simulation of a process so that the difference between deposition thicknesses deposited on the plurality of substrates W positioned at different vertical levels in the interior space of the first tube 100a is small.

In some embodiments, each of the plurality of mini exhaust holes may have a horizontal width varying away from the lower surface of the first tube 100a. The first mini exhaust hole 1211 may have a horizontal width increasing away from the lower surface of the first tube 100a. For example, each of the plurality of mini exhaust holes may have a quadrangular shape or a trapezoidal shape in the second direction D2 (see FIG. 2).

In some embodiments, the multi-exhaust hole region 121a may include first to fourth mini exhaust holes 1211, 1212a, 1213, and 1214a. A first width W1211, that is the horizontal width of the first mini exhaust hole 1211, may be different from a second width W1212a, that is the horizontal width of the second mini exhaust hole 1212a. Although FIG. 6 shows that the height H1211 of the first mini exhaust hole 1211 is the same as the height of the second mini exhaust hole 1212a, the plurality of mini exhaust holes are not limited thereto and the height H1211 of the first mini exhaust hole 1211 may be different from the height of the second mini exhaust hole 1212a. In addition, although FIG. 6 shows that a mini exhaust hole having a relatively large horizontal width and a mini exhaust hole having a relatively small horizontal width are alternately disposed, the plurality of mini exhaust holes are not limited thereto and an arrangement of mini exhaust holes may vary depending on a design.

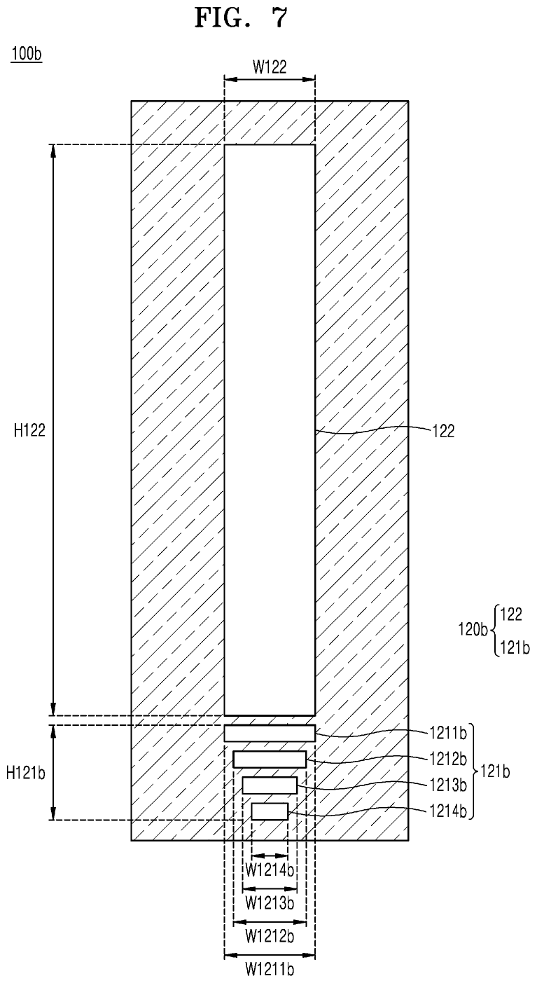

Referring to FIG. 7, the first tube 100b may include the plurality of exhaust holes 120b. The plurality of exhaust holes 120b may include the main exhaust hole 122 and a multi-exhaust hole region 121b. The multi-exhaust hole region 121b may include a plurality of mini exhaust holes.

The plurality of mini exhaust holes of the multi-exhaust hole region 121b may have different horizontal widths. The horizontal widths of the plurality of mini exhaust holes of the multi-exhaust hole region 121b may increase toward the main exhaust hole 122. For example, the horizontal width of the multi-exhaust hole region 121b may increase toward the main exhaust hole 122.

In some embodiments the multi-exhaust hole region 121b may include first to fourth mini exhaust holes 1211b, 1212b, 1213b, and 1214b. The first to fourth mini exhaust holes 1211b, 1212b, 1213b, and 1214b may be spaced apart from each other in the first direction D1 (see FIG. 2). The first to fourth mini exhaust holes 1211b, 1212b, 1213b, and 1214b may be disposed in their order in the vertical direction from the bottom of the main exhaust hole 122. The horizontal width of the first mini exhaust hole 1211b may be a first width W1211b, the horizontal width of the second mini exhaust hole 1212b may be a second width W1212b, the horizontal width of the third mini exhaust hole 1213b may be a third width W1213b, and the horizontal width of the fourth mini exhaust hole 1214b may be a fourth width W1214b. Herein, the first width W1211b may be greater than the second width W1212b, the second width W1212b may be greater than the third width W1213b, and the third width W1213b may be greater than the fourth width W1214b. For example, as a mini exhaust hole is disposed closer to the main exhaust hole 122, the horizontal width of the mini exhaust hole may increase.

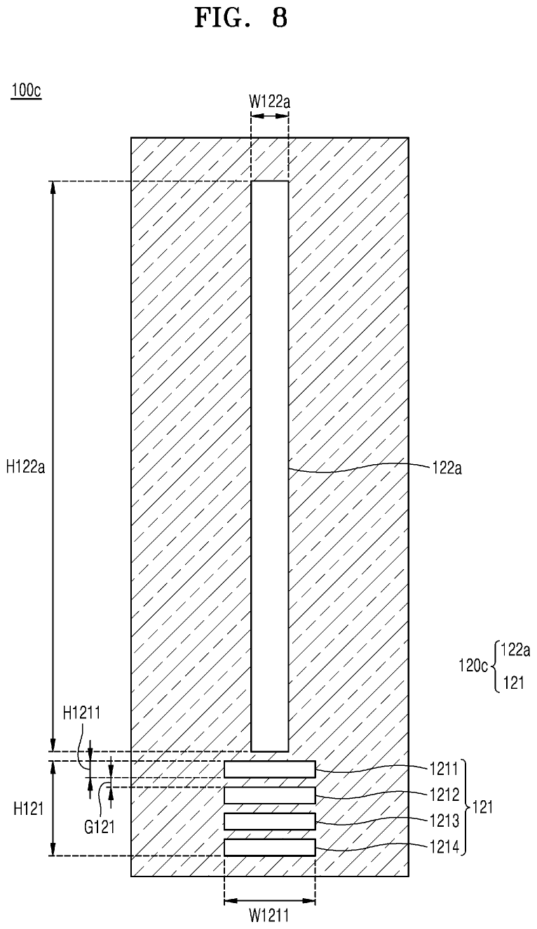

Referring to FIG. 8, the first tube 100c may include the plurality of exhaust holes 120c. The plurality of exhaust holes 120c may include a main exhaust hole 122a and the multi-exhaust hole region 121. The multi-exhaust hole region 121 may include a plurality of mini exhaust holes.

The horizontal width of the multi-exhaust hole region 121 may be different from the horizontal width of the main exhaust hole 122a. When the horizontal width of the multi-exhaust hole region 121 is the first width W1211 and the horizontal width of the main exhaust hole 122a is a second width W122a, the first width W1211 may be different from the second width W122a. In some embodiments, the first width W1211 may be greater than the second width W122a. However, the plurality of exhaust holes 120c are not limited thereto, and the first width W1211 may be less than the second width W122a.

In some embodiments, a height H122a of the main exhaust hole 122a may be greater than the height H121 of the multi-exhaust hole region 121. The height H122a of the main exhaust hole 122a may be greater than the second width W122a that is the horizontal width of the main exhaust hole 122a. In some embodiments, the main exhaust hole 122a may have a shape with the height H122a greater than the horizontal width (i.e., second width W122a).

In some embodiments, the multi-exhaust hole region 121 may include the first to fourth mini exhaust holes 1211, 1212, 1213, and 1214. When the horizontal width of the first mini exhaust hole 1211 is the first width W1211, the first width W1211 may be different from the second width W122a. For example, the horizontal width of each of the plurality of exhaust holes of the multi-exhaust hole region 121 may be different from the horizontal width of the main exhaust hole 122a. In some embodiments, the multi-exhaust hole region 121 may be the multi-exhaust hole region 121 of FIG. 4, the multi-exhaust hole region 121a of FIG. 6, or the multi-exhaust hole region 121b of FIG. 7 described above. For example, the sizes of the plurality of exhaust holes of the multi-exhaust hole region 121 may be independent from the size of the main exhaust hole 122a.

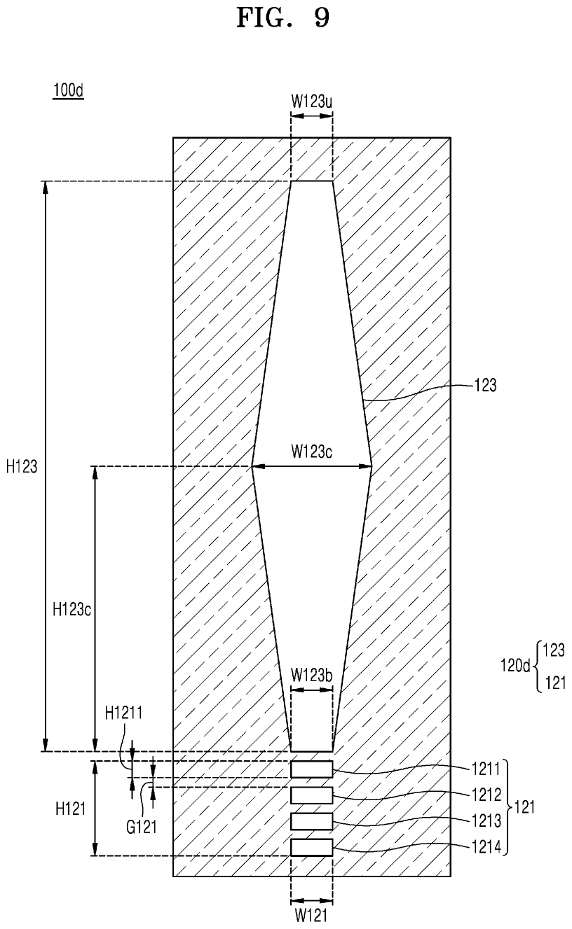

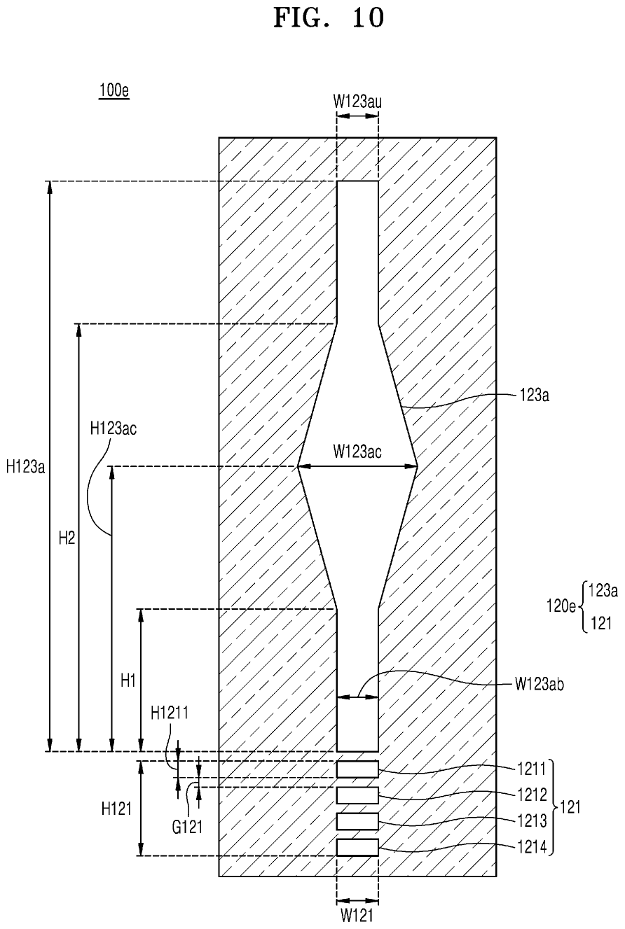

FIGS. 9 and 10 are front views schematically illustrating first tubes 100d and 100e of a substrate processing device, according to an embodiment.

Referring to FIGS. 9 and 10, embodiments of respective pluralities of exhaust holes 120d and 120e of the first tubes 100d and 100e are particularly described. Hereinafter, when describing the pluralities of exhaust holes 120d and 120c of FIGS. 9 and 10, a description made for the plurality of exhaust holes 120 of FIG. 4 is omitted and differences therefrom are described.

The first tube 100d may include the plurality of exhaust holes 120d. The plurality of exhaust holes 120d may include a main exhaust hole 123 and the multi-exhaust hole region 121. The multi-exhaust hole region 121 of FIG. 9 may be the multi-exhaust hole region 121 of FIG. 4, the multi-exhaust hole region 121a of FIG. 6, or the multi-exhaust hole region 121b of FIG. 7 described above.

The main exhaust hole 123 may have a horizontal width varying in a partial region. For example, in the main exhaust hole 123, the horizontal width of at least a portion may be different from the horizontal width of the other portion. In other words, the main exhaust hole 123 may have a horizontal width varying according to vertical levels.

The main exhaust hole 123 may include an upper side and a lower side spaced apart from each other in the first direction D1 in a sidewall forming the main exhaust hole 123. The main exhaust hole 123 may include a virtual horizontal surface spaced by a certain distance from the upper side and the lower side in the first direction D1. For example, a distance H123 from the lower side to the upper side of the main exhaust hole 123 may be greater than a distance H123c from the lower side to the virtual horizontal surface. The distance H123 may be two times the distance H123c.

In some embodiments, the horizontal width of at least one of the upper side and the lower side of the main exhaust hole 123 may be different from the horizontal width of the virtual horizontal surface of the main exhaust hole 123.

In some embodiments, the horizontal width of at least a portion of the main exhaust hole 123 may be different from the horizontal width of at least one of the upper side and the lower side of the main exhaust hole 123. For example, at least a portion of the main exhaust hole 123 may include a virtual central surface.

Hereinafter, the upper side of the main exhaust hole 123 may be referred to as an upper surface of the main exhaust hole 123 and the lower side of the main exhaust hole 123 may be referred to as a lower surface of the main exhaust hole 123. In some embodiments, the virtual horizontal surface of the main exhaust hole 123 may be at an intermediate point of the height of the first tube 100d. For example, the main exhaust hole 123 may extend in the vertical direction by passing through the intermediate point of the height of the first tube 100d.

As shown in FIG. 9, in some embodiments, the main exhaust hole 123 may have a first width W123u as the horizontal width of the upper surface of the main exhaust hole 123, a second width W123b as the horizontal width of the lower surface of the main exhaust hole 123, and a third width W123c as the horizontal width of the virtual horizontal surface of the main exhaust hole 123. The first width W123u may be the same as the second width W123b, and the third width W123c may be greater than each of the first width W123u and the second width W123b. For example, the main exhaust hole 123 may have a shape having a horizontal width increasing toward the virtual horizontal surface. Particularly, the main exhaust hole 123 may have a shape having a horizontal width increasing toward the intermediate point of the height of the first tube 100d. In some embodiments, the intermediate point of the height of the first tube 100d may be substantially the same as a vertical level of the virtual horizontal surface. Although FIG. 9 shows that the main exhaust hole 123 has a polygonal shape such as a hexagonal shape, the main exhaust hole 123 is not limited thereto and may have a shape with rounded corners.

As shown in FIG. 10, in some embodiments, a main exhaust hole 123a may include first to third regions. The second region may be between the first region and the third region. The first region is discriminated from the second region with reference to a virtual surface spaced apart by a first distance H1 from the lower surface of the main exhaust hole 123a and the second region is discriminated from the third region with reference to a virtual surface spaced apart by a second distance H2 from the lower surface of the main exhaust hole 123a. For example, the height of the first region may be the first distance H1 and the height of the second region may be a value obtained by subtracting the first distance H1 from the second distance H2. In this case, a spaced distance H123ac between a virtual horizontal surface of the main exhaust hole 123a and the lower surface of the main exhaust hole 123a may be greater than the first distance H1 and less than the second distance H2. For example, the virtual horizontal surface of the main exhaust hole 123a may be in the second region.

In some embodiments, the main exhaust hole 123a may have a constant horizontal width in the first region and have a constant horizontal width in the third region. For example, the main exhaust hole 123a may have a constant horizontal width as a first width W123ab in the first region and have a constant horizontal width as a third width W123au in the third region. However, the first width W123ab and the third width W123au are independent from each other and thus may be the same as or different from each other. The main exhaust hole 123a may have a horizontal width varying in the second region. In some embodiments, the main exhaust hole 123a may have a horizontal width increasing toward the virtual horizontal surface in the second region.

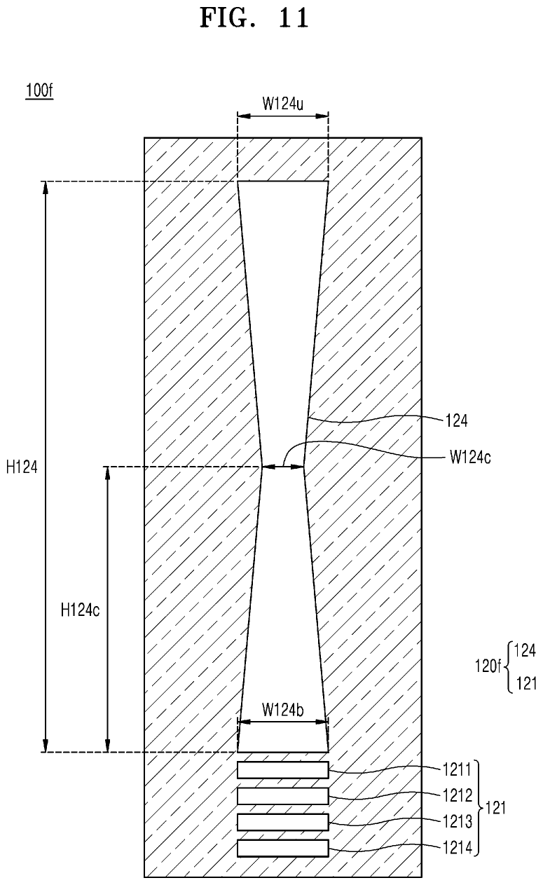

FIGS. 11 to 13 are front views schematically illustrating first tubes 100f, 100g, and 100h of a substrate processing device, according to an embodiment.

Referring to FIGS. 11 to 13, embodiments of respective pluralities of exhaust holes 120f, 120g, and 120h of the first tubes 100f, 100g, and 100h are particularly described. Hereinafter, when describing the pluralities of exhaust holes 120f, 120g, and 120h of FIGS. 11 to 13, a description made for the plurality of exhaust holes 120d of FIG. 9 is omitted and differences therefrom are described.

The first tube 100f may include the plurality of exhaust holes 120f. The plurality of exhaust holes 120f may include a main exhaust hole 124 and the multi-exhaust hole region 121. The multi-exhaust hole region 121 of FIG. 11 may be the multi-exhaust hole region 121 of FIG. 4, the multi-exhaust hole region 121a of FIG. 6, or the multi-exhaust hole region 121b of FIG. 7 described above.

The main exhaust hole 124 may have a horizontal width varying in a partial region. For example, in the main exhaust hole 124, the horizontal width of at least a portion may be different from the horizontal width of the other portion. In other words, the main exhaust hole 124 may have a horizontal width varying according to vertical levels.

The main exhaust hole 124 may include an upper side and a lower side spaced apart from each other in the first direction D1 in a sidewall forming the main exhaust hole 124. The main exhaust hole 124 may include a virtual horizontal surface spaced by the same distance from the upper side and the lower side in the first direction D1. For example, a distance H124 from the lower side to the upper side of the main exhaust hole 124 may be two times a distance H124c from the lower side to the virtual horizontal surface.

As shown in FIG. 11, in some embodiments, the main exhaust hole 124 may have a first width W124u as the horizontal width of the upper surface of the main exhaust hole 124, a second width W124b as the horizontal width of the lower surface of the main exhaust hole 124, and a third width W124c as the horizontal width of the virtual horizontal surface of the main exhaust hole 124. The first width W124u may be the same as the second width W124b, and the third width W124c may be less than each of the first width W124u and the second width W124b. For example, the main exhaust hole 124 may have a shape having a horizontal width decreasing toward the virtual horizontal surface.

However, although FIG. 11 shows that the main exhaust hole 124 has the virtual horizontal surface at the center of the main exhaust hole 124, the main exhaust hole 124 is not limited thereto and the virtual horizontal surface may be between the upper surface and the lower surface of the main exhaust hole 124. For example, the main exhaust hole 124 may have a shape having a horizontal width decreasing toward an intermediate point of the height of the first tube 100f. The intermediate point of the height of the first tube 100f may be between the upper surface and the lower surface of the main exhaust hole 124. In addition, although FIG. 11 shows that the main exhaust hole 124 has a polygonal shape such as a hexagonal shape, the main exhaust hole 124 is not limited thereto and may have a shape with rounded corners.

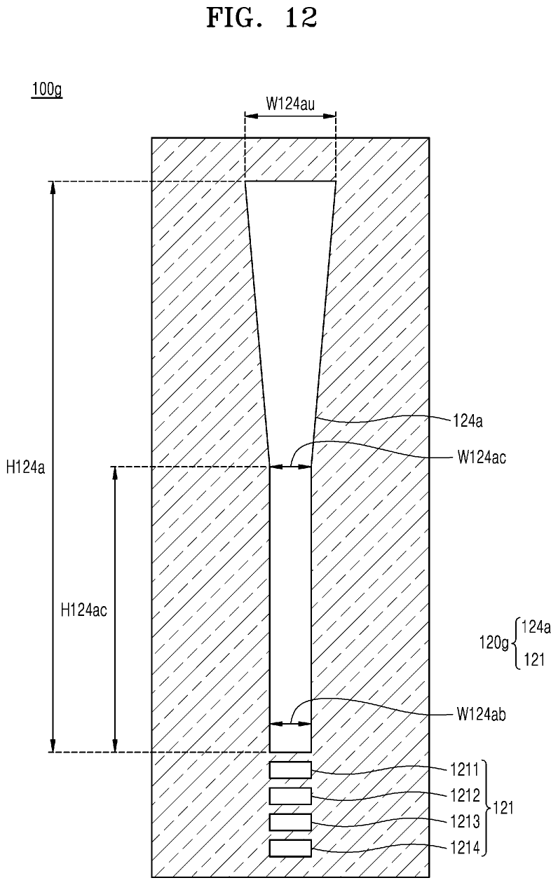

As shown in FIG. 12, the first tube 100g may include the plurality of exhaust holes 120g. The plurality of exhaust holes 120g may include a main exhaust hole 124a and the multi-exhaust hole region 121. In some embodiments, the main exhaust hole 124a may have a first width W124au as the horizontal width of an upper surface thereof, a second width W124ab as the horizontal width of a lower surface thereof, and a third width W124ac as the horizontal width of a virtual horizontal surface thereof. The second width W124ab may be the same as the third width W124ac, and the first width W124au may be greater than each of the second width W124ab and the third width W124ac. For example, the main exhaust hole 124a may have a shape having a constant horizontal width from the lower surface of the main exhaust hole 124a to the virtual horizontal surface and having a horizontal width gradually increasing toward the upper surface of the main exhaust hole 124a.

However, although FIG. 12 shows that the main exhaust hole 124a has the virtual horizontal surface at the center of the main exhaust hole 124a, the main exhaust hole 124a is not limited thereto and the virtual horizontal surface may be between the upper surface and the lower surface of the main exhaust hole 124a. For example, the main exhaust hole 124a may have a constant horizontal width from the lower surface of the main exhaust hole 124a to the intermediate point of the height of the first tube 100g and have a horizontal width gradually increasing from the intermediate point of the height of the first tube 100g to the upper surface of the main exhaust hole 124a. Herein, the intermediate point of the height of the first tube 100g may be between the upper surface and the lower surface of the main exhaust hole 124a.

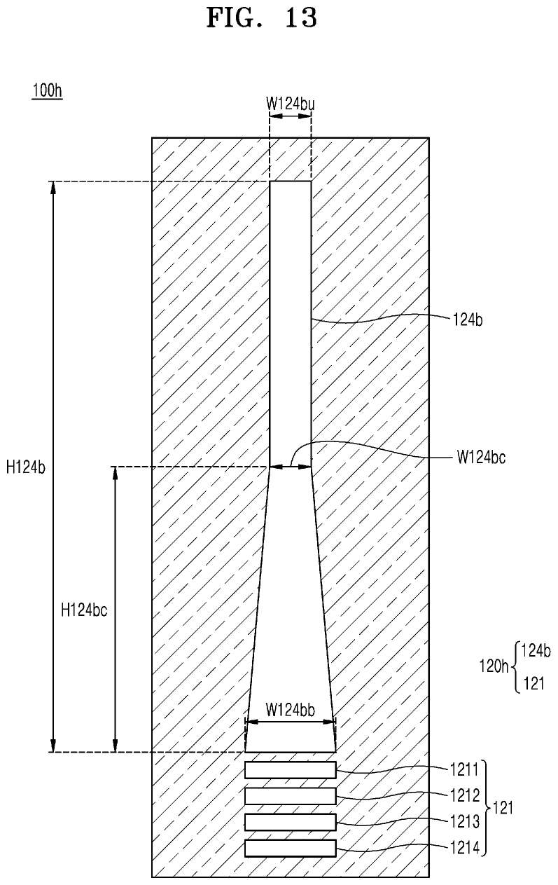

As shown in FIG. 13, the first tube 100h may include the plurality of exhaust holes 120h. The plurality of exhaust holes 120h may include a main exhaust hole 124b and the multi-exhaust hole region 121. In some embodiments, the main exhaust hole 124b may have a first width W124bu as the horizontal width of an upper surface thereof, a second width W124bb as the horizontal width of a lower surface thereof, and a third width W124bc as the horizontal width of a virtual horizontal surface thereof. The first width W124bu may be the same as the third width W124bc, and the second width W124bb may be greater than each of the first width W124bu and the third width W124bc. For example, the main exhaust hole 124b may have a shape having a horizontal width gradually decreasing from the lower surface of the main exhaust hole 124b to the virtual horizontal surface and having a constant horizontal width from the virtual horizontal surface to the upper surface of the main exhaust hole 124b.

However, although FIG. 13 shows that the main exhaust hole 124b has the virtual horizontal surface at the center of the main exhaust hole 124b, the main exhaust hole 124b is not limited thereto and the virtual horizontal surface may be between the upper surface and the lower surface of the main exhaust hole 124b. For example, the main exhaust hole 124b may have a horizontal width gradually decreasing from the lower surface of the main exhaust hole 124b to an intermediate point of the height of the first tube 100h and have a constant horizontal width from the intermediate point of the height of the first tube 100h to the upper surface of the main exhaust hole 124b. Herein, the intermediate point of the height of the first tube 100h may be between the upper surface and the lower surface of the main exhaust hole 124b.

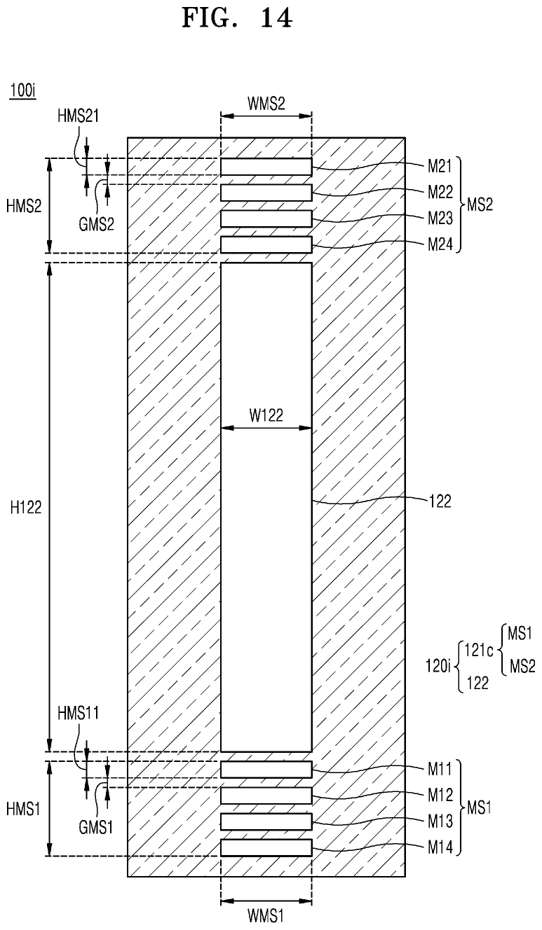

FIGS. 14 to 16 are front views schematically illustrating first tubes 100i, 100j, and 100k of a substrate processing device, according to an embodiment.

Referring to FIGS. 14 to 16, embodiments of respective pluralities of exhaust holes 120i, 120j, and 120k of the first tubes 100i, 100j, and 100k are particularly described. Hereinafter, when describing the pluralities of exhaust holes 120i, 120j, and 120k of FIGS. 14 to 16, a description made for the plurality of exhaust holes 120 of FIG. 4 is omitted and differences therefrom are described.

Referring to FIGS. 14 to 16, each of the pluralities of exhaust holes 120i, 120j, and 120k may include a multi-exhaust hole region 121c. The multi-exhaust hole region 121c may include a first region MS1 and a second region MS2. The first region MS1 may be spaced apart from the second region MS2 in the first direction D1. In some embodiments, the first region MS1 may be spaced apart from the second region MS2 with the main exhaust hole 122, 123, or 124 therebetween. For example, the first region MS1 may be under the main exhaust hole 122, 123, or 124 in the first direction D1 and the second region MS2 may be above the main exhaust hole 122, 123, or 124 in the first direction D1. Some of the plurality of mini exhaust holes may be under the main exhaust hole 122, 123, or 124 in the vertical direction and the others thereof may be above the main exhaust hole 122, 123, or 124 in the vertical direction.

The multi-exhaust hole region 121c may include the plurality of mini exhaust holes. The plurality of mini exhaust holes may include a first group of mini exhaust holes M11, M12, M13, and M14 disposed in the first region MS1 of the multi-exhaust hole region 121c, and a second group of mini exhaust holes M21, M22, M23, and M24 disposed in the second region MS2 of the multi-exhaust hole region 121c. The first group of mini exhaust holes M11, M12, M13, and M14 may be disposed under the main exhaust hole 122, 123, or 124 in the first direction D1. The second group of mini exhaust holes M21, M22, M23, and M24 may be disposed above the main exhaust hole 122, 123, or 124 in the first direction D1. The first group of mini exhaust holes M11, M12, M13, and M14, the main exhaust hole 122, 123, or 124, and the second group of mini exhaust holes M21, M22, M23, and M24 may be in a line in the first direction D1.

Although FIGS. 14 to 16 show that the first group of mini exhaust holes M11, M12, M13, and M14 includes the same number of mini exhaust holes as the second group of mini exhaust holes M21, M22, M23, and M24, the first tubes 100i, 100j, and 100k are not limited thereto and the first group of mini exhaust holes M11, M12, M13, and M14 may include a different number of mini exhaust holes from those of the second group of mini exhaust holes M21, M22, M23, and M24.

A height HMS11 of the first mini exhaust hole M11 included in the first group of mini exhaust holes M11, M12, M13, and M14 is independent from a height HMS21 of the fifth mini exhaust hole M21 included in the second group of mini exhaust holes M21, M22, M23, and M24. For example, the height HMS11 of the first mini exhaust hole M11 may be the same as or different from the height HMS21 of the fifth mini exhaust hole M21. The heights of mini exhaust holes included in the first group of mini exhaust holes M11, M12, M13, and M14 and the heights of mini exhaust holes included in the second group of mini exhaust holes M21, M22, M23, and M24 may have different numeric values depending on process procedures.

A length (i.e., height) HMS1 of the first region MS1 of the multi-exhaust hole region 121c in the first direction D1 is independent from a length (i.e., height) HMS2 of the second region MS2 of the multi-exhaust hole region 121c in the first direction D1. For example, the length HMS1 of the first region MS1 in the first direction D1 may be the sum of respective heights of the plurality of mini exhaust holes included in the first region MS1 and respective spaced distances GMS1 between the plurality of mini exhaust holes. The length HMS2 of the second region MS2 in the first direction D1 may be the sum of respective heights of the plurality of mini exhaust holes included in the second region MS2 and respective spaced distances GMS2 between the plurality of mini exhaust holes. Accordingly, the number and heights of mini exhaust holes included in the first region MS1 or the second region MS2 and respective spaced distances between the mini exhaust holes may have different numeric values depending on target process operations, and thus, the length HMS1 of the first region MS1 in the first direction D1 may be different from the length HMS2 of the second region MS2 in the first direction D1.

A horizontal width WMS1 of the first region MS1 of the multi-exhaust hole region 121c is independent from a horizontal width WMS2 of the second region MS2 of the multi-exhaust hole region 121c. The horizontal width WMS1 of the first region MS1 of the multi-exhaust hole region 121c may be the horizontal width of a mini exhaust hole having the greatest horizontal width in the first group of mini exhaust holes M11, M12, M13, and M14 and the horizontal width WMS2 of the second region MS2 of the multi-exhaust hole region 121c may be the horizontal width of a mini exhaust hole having the greatest horizontal width in the second group of mini exhaust holes M21, M22, M23, and M24. For example, the horizontal width of each of the mini exhaust holes included in the first region MS1 may be independent from the horizontal width of each of the mini exhaust holes included in the second region MS2.

In some embodiments, the first region MS1 may be different from the second region MS2 in at least one of the horizontal widths WMS and WMS2 and the lengths HMS1 and HMS2 in the first direction D1. Accordingly, the first region MS1 may have a size different from that of the second region MS2.

As shown in FIG. 14, in some embodiments, the main exhaust hole 122 may have a constant horizontal width W122 from the upper surface to the lower surface thereof. The main exhaust hole 122 may be the main exhaust hole 122 of FIG. 4 or the main exhaust hole 122a of FIG. 8 described above.

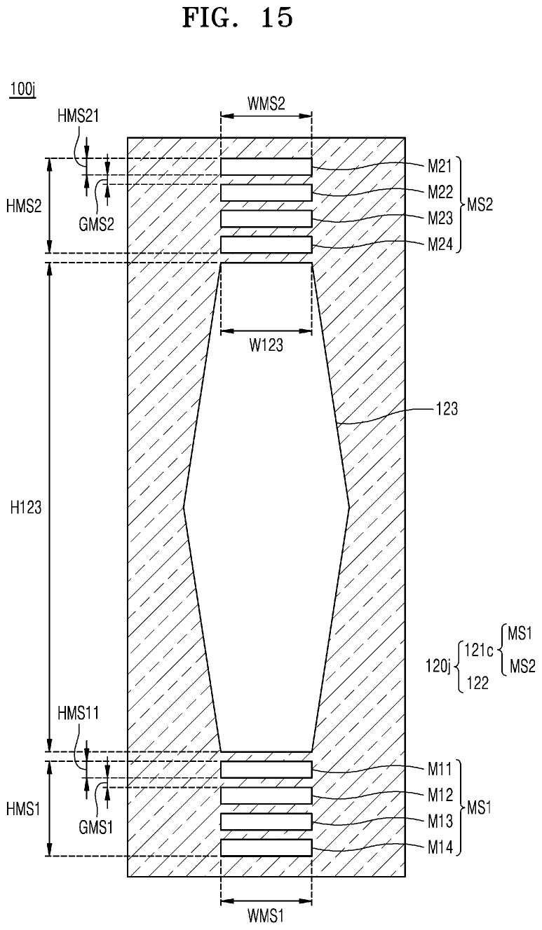

As shown in FIG. 15, in some embodiments, in the main exhaust hole 123, the horizontal width of a virtual horizontal surface between the upper surface and the lower surface of the main exhaust hole 123 may be greater than a horizontal width W123 of at least one of the upper surface and the lower surface of the main exhaust hole 123. In some embodiments, the main exhaust hole 123 may be the main exhaust hole 123 of FIG. 9 or the main exhaust hole 123a of FIG. 10 described above.

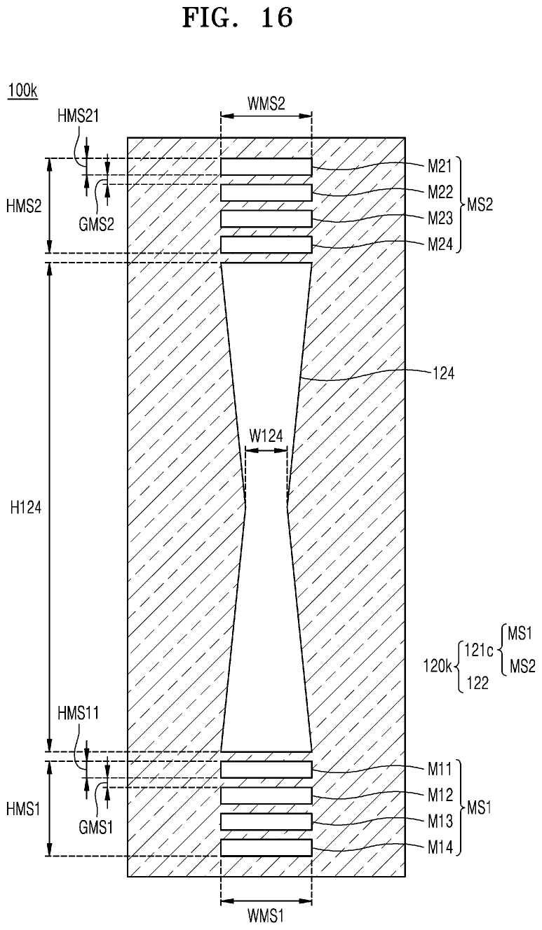

As shown in FIG. 16, in some embodiments, in the main exhaust hole 124, a horizontal width W124 of a virtual horizontal surface between the upper surface and the lower surface of the main exhaust hole 124 may be less than the horizontal width of at least one of the upper surface and the lower surface of the main exhaust hole 124. In some embodiments, the main exhaust hole 124 may be the main exhaust hole 124 of FIG. 11, the main exhaust hole 124a of FIG. 12, or the main exhaust hole 124b of FIG. 13 described above.

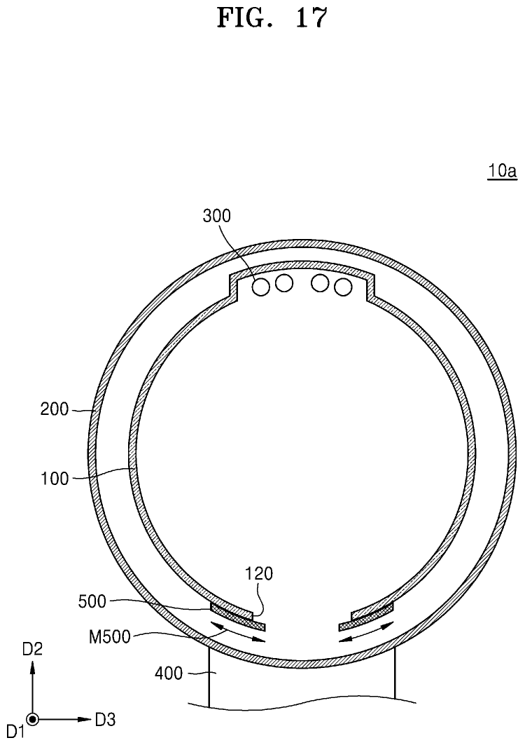

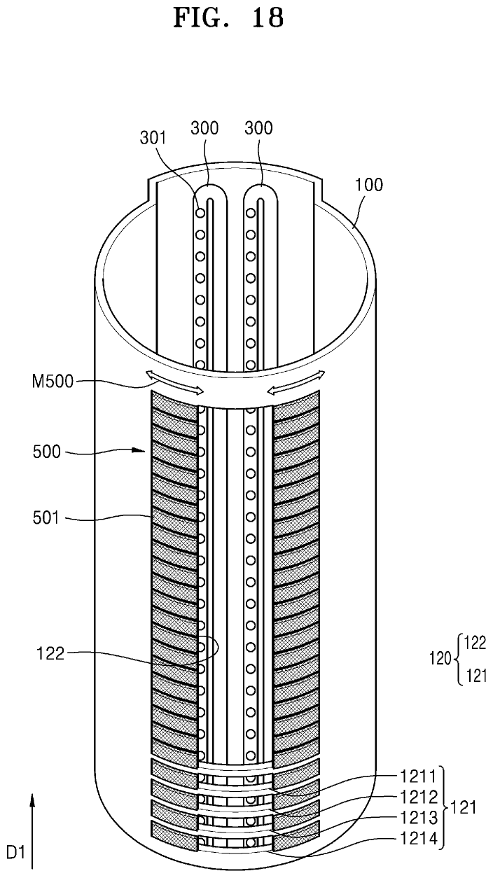

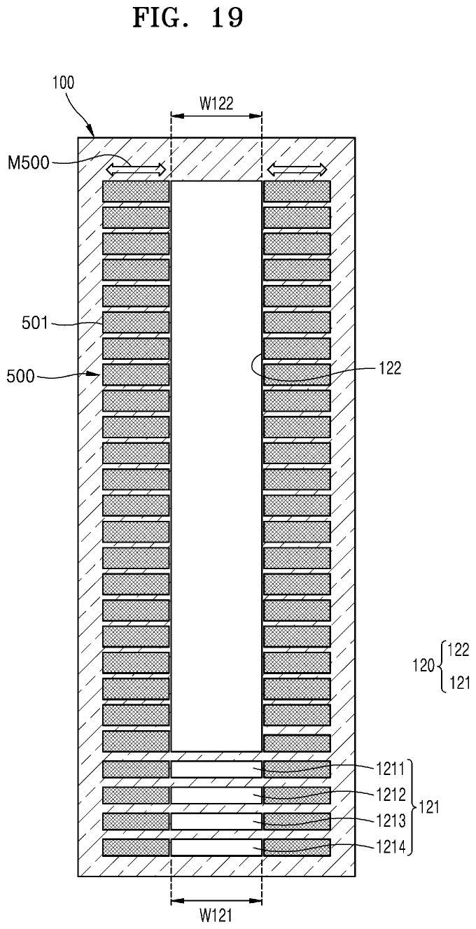

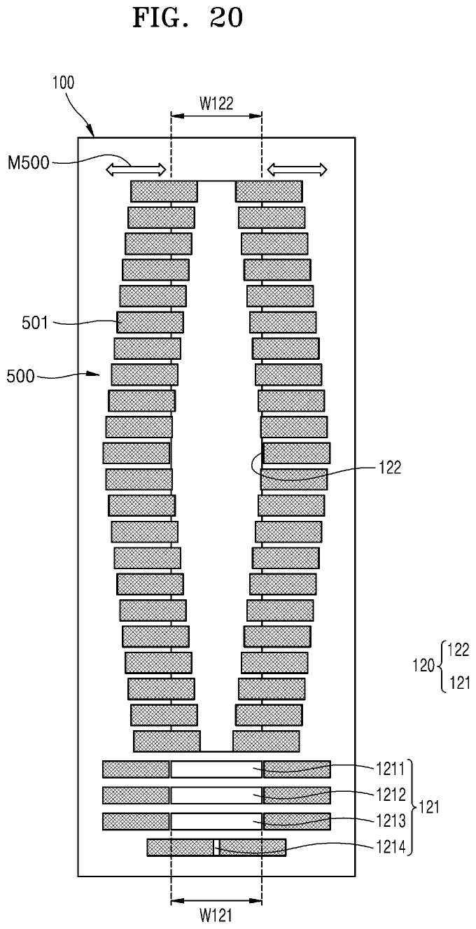

FIG. 17 is a top view schematically illustrating a substrate processing device 10a according to some embodiments. FIG. 18 is a perspective view schematically illustrating a portion of the substrate processing device 10a of FIG. 17. FIGS. 19 and 20 are front views schematically illustrating the first tube 100 of the substrate processing device 10a of FIG. 17.

Referring to FIGS. 17 to 20, the substrate processing device 10a may include the first tube 100, the second tube 200, the process gas supply line 300, the exhaust port 400, and a cover plate 500.

Hereinafter, when describing the substrate processing device 10a, a description made for the substrate processing device 10 of FIG. 2 with reference to FIGS. 1 to 5 is omitted and differences therefrom are described. The second tube 200, the process gas supply line 300, and the exhaust port 400 may be substantially the same as the second tube 200, the process gas supply line 300, and the exhaust port 400 of FIG. 2 described above, respectively.

The first tube 100 may be the first tube 100 of FIG. 4, the first tube 100a of FIG. 6, the first tube 100b of FIG. 7, the first tube 100c of FIG. 8, the first tube 100d of FIG. 9, the first tube 100c of FIG. 10, the first tube 100f of FIG. 11, the first tube 100g of FIG. 12, the first tube 100h of FIG. 13, the first tube 100i of FIG. 14, the first tube 100j of FIG. 15, or the first tube 100k of FIG. 16.

The cover plate 500 may be mounted on the sidewall of the first tube 100. Although FIG. 17 shows that the cover plate 500 is mounted on the outer surface of the sidewall of the first tube 100, the cover plate 500 is not limited thereto and may be mounted on the inner surface of the sidewall of the first tube 100.

The cover plate 500 may move on the sidewall of the first tube 100. The cover plate 500 may move along the sidewall of the first tube 100 and cover at least portions of the plurality of exhaust holes 120 of the first tube 100. The cover plate 500 may be at one side or both sides of at least one of the plurality of exhaust holes 120 and cover at least a portion of the at least one of the plurality of exhaust holes 120 by moving (M500) along the sidewall of the first tube 100 in the horizontal direction. An exhaust hole covered by the cover plate 500 may have a reduced size of a hole through which the process gas inside the first tube 100 moves to the outside, thereby reducing the discharge speed of the process gas in the substrate processing device 10a. In addition, the cover plate 500 may fully cover one of the plurality of exhaust holes 120 and the process gas may not be discharged through the exhaust hole covered by the cover plate 500.

The substrate processing device 10a according to aspects of the inventive concept may adjust the discharge speed of the process gas by adjusting the size of each of the plurality of exhaust holes 120 by the cover plate 500.

In some embodiments, the cover plate 500 may have an arc shape. When the cover plate 500 has an arc shape, the curvature of the cover plate 500 may be the same as the curvature of the sidewall of the first tube 100. Accordingly, when the cover plate 500 moves along the sidewall of the first tube 100, a phenomenon that the cover plate 500 collides with the first tube 100 may be suppressed.

In some embodiments, the cover plate 500 may include a plurality of plates 501. The plurality of plates 501 may individually move to close at least some of the plurality of exhaust holes 120. Accordingly, the main exhaust hole 122 may have a horizontal width varying according to vertical levels. Although FIG. 18 shows that the cover plate 500 includes the plurality of plates 501, the cover plate 500 is not limited thereto and may include one plate to simultaneously control the sizes of the main exhaust hole 122 and the multi-exhaust hole region 121.

Referring to FIGS. 19 and 20, some of a plurality of plates 501 may be mounted at both sides of the main exhaust hole 122 in a line in the vertical direction. The plurality of plates 501 mounted in a line in the vertical direction may move independently from each other so that the horizontal width of the main exhaust hole 122 varies according to vertical levels of the main exhaust hole 122. For example, respective moving distances of the plurality of plates 501 mounted in a line in the vertical direction may be different from each other so that a covered area of the main exhaust hole 122 varies according to vertical levels of the main exhaust hole 122.

Referring to FIGS. 19 and 20, some of a plurality of plates 501 may be mounted at both sides of the first to fourth mini exhaust holes 1211, 1212, 1213, and 1214 of the multi-exhaust hole region 121. In some embodiments, if the height of each of the plurality of mini exhaust holes is the same as the height of the cover plate 500, one plate may be mounted at one side of one mini exhaust hole.

In some embodiments, the cover plate 500 at both sides of the fourth mini exhaust hole 1214 among the first to fourth mini exhaust holes 1211, 1212, 1213, and 1214 may horizontally move (M500) to reduce the horizontal width of the fourth mini exhaust hole 1214. For example, the plurality of plates 501 at both sides of a mini exhaust hole may horizontally move (M500) to adjust the horizontal width of the mini exhaust hole, and as a result, the horizontal widths of the plurality of mini exhaust holes may be different from each other.

In some embodiments, the plurality of plates 501 may perfectly close (i.e., without a partial opening) some of the first to fourth mini exhaust holes 1211, 1212, 1213, and 1214. Accordingly, the cover plate 500 may be used to adjust the number of mini exhaust holes opened among the first to fourth mini exhaust holes 1211, 1212, 1213, and 1214 of the multi-exhaust hole region 121, through which the process gas flows.

The plurality of plates 501 at both sides of the multi-exhaust hole region 121 and the plurality of plates 501 at both sides of the main exhaust hole 122 may independently move. Accordingly, the size of the horizontal width of the main exhaust hole 122 and the size of the horizontal width of the multi-exhaust hole region 121 may be independently adjusted.

In some embodiments, the substrate processing device 10a may further include a controller (not shown) configured to control motion of the cover plate 500. The controller may be connected to an actuator (not shown), configured to provide a driving force to the cover plate 500, to control a moving distance of the cover plate 500. For example, the controller may move the cover plate 500 based on a value preset according to the type of process gas to be supplied to the first tube 100 and a processing process.

While aspects of the inventive concept have been particularly shown and described with reference to embodiments thereof, it will be understood that various changes in form and details may be made therein without departing from the spirit and scope of the following claims.

What is claimed is:

1. A substrate processing device comprising:
a first tube configured to load a substrate in an interior space thereof;
a second tube configured to include the first tube therein; and
a process gas supply line configured to inject process gas to the interior space of the first tube,
wherein the first tube has a plurality of exhaust holes penetrating a sidewall of the first tube, the plurality of exhaust holes comprise a main exhaust hole and a multi-exhaust hole region disposed in a line in the vertical direction, the multi-exhaust hole region comprises a plurality of auxiliary exhaust holes, and the height of each of the plurality of auxiliary exhaust holes is less than the height of the main exhaust hole.

2. The substrate processing device of claim 1, wherein the process gas supply line extends in the vertical direction inside the first tube, and the plurality of exhaust holes face the process gas supply line.

3. The substrate processing device of claim 1, wherein the multi-exhaust hole region of the plurality of exhaust holes is under the main exhaust hole of the plurality of exhaust holes.

4. The substrate processing device of claim 1, further comprising an exhaust port connected to the second tube and configured to discharge the process gas to the outside,
wherein a vertical level of the multi-exhaust hole region is the same as a vertical level of the exhaust port.

5. The substrate processing device of claim 1, wherein each of the plurality of auxiliary exhaust holes has a horizontal width that is greater than a height of each of the plurality of auxiliary exhaust holes.

6. The substrate processing device of claim 1, wherein the horizontal width of each of the plurality of auxiliary exhaust holes of the multi-exhaust hole region is different from the horizontal width of the main exhaust hole.

7. The substrate processing device of claim 1, wherein two adjacent auxiliary exhaust holes among the plurality of auxiliary exhaust holes of the multi-exhaust hole region are spaced apart from each other by about 2 mm to about 5 mm in the vertical direction.

8. The substrate processing device of claim 1, wherein the height of the main exhaust hole is about 3 times to about 15 times the height of the multi-exhaust hole region.

9. A substrate processing device comprising:
a first tube configured to load a substrate in an interior space thereof;
a second tube configured to include the first tube therein; and
a process gas supply line configured to inject process gas to the interior space of the first tube,
wherein the first tube has a plurality of exhaust holes penetrating a sidewall of the first tube, the plurality of exhaust holes comprise a main exhaust hole and a multi-exhaust hole region, the multi-exhaust hole region comprises a plurality of auxiliary exhaust holes, the main exhaust hole extends in the vertical direction after passing through an intermediate point of the height of the first tube, and the horizontal width of at least a portion of the main exhaust hole is different from at least one of the horizontal width of a lower surface of the main exhaust hole and the horizontal width of an upper surface of the main exhaust hole.

10. The substrate processing device of claim 9, wherein the main exhaust hole has a horizontal width increasing toward the intermediate point of the height of the first tube.

11. The substrate processing device of claim 9, wherein the multi-exhaust hole region comprises a first region and a second region, the first region being spaced apart from the second region in the vertical direction.

12. The substrate processing device of claim 11, wherein the first region is spaced apart from the second region with the main exhaust hole therebetween.

13. The substrate processing device of claim 11, wherein the number of auxiliary exhaust holes in the first region is different from the number of auxiliary exhaust holes in the second region.

14. The substrate processing device of claim 11, wherein the plurality of auxiliary exhaust holes of the multi-exhaust hole region comprise a first auxiliary exhaust hole group and a second auxiliary exhaust hole group, the first auxiliary exhaust hole group comprises a plurality of auxiliary exhaust holes in the first region of the multi-exhaust hole region, the second auxiliary exhaust hole group comprises a plurality of auxiliary exhaust holes in the second region of the multi-exhaust hole region, and the first auxiliary exhaust hole group, the main exhaust hole, and the second auxiliary exhaust hole group are disposed in a line in the vertical direction.

15. The substrate processing device of claim 14, wherein the first region of the multi-exhaust hole region is different from the second region of the multi-exhaust hole region in at least one of a horizontal width and a height.

16. The substrate processing device of claim 9, further comprising a cover plate movably mounted on a sidewall of the first tube and configured to cover at least portions of the plurality of exhaust holes.

17. The substrate processing device of claim 9, wherein the main exhaust hole comprises the upper surface and the lower surface extending in a direction that is perpendicular to the vertical direction, and the width of the upper surface is the same as the width of the lower surface.

18. The substrate processing device of claim 17, wherein the width of the lower surface of the main exhaust hole is the same as the horizontal width of the multi-exhaust hole region.

19. The substrate processing device of claim 9, wherein the main exhaust hole comprises the upper surface and the lower surface extending in a direction that is perpendicular to the vertical direction, a vertical level of an intermediate point of the height of the main exhaust hole is a first level, and the main exhaust hole has a constant horizontal width from the lower surface to the first level and a horizontal width increasing from the first level to the upper surface.

20. A substrate processing device comprising:
a first tube configured to load a substrate in an interior space thereof;
a second tube configured to include the first tube therein and having a through hole in a sidewall thereof;
a process gas supply line configured to inject process gas to the interior space of the first tube; and
an exhaust port connected to the through hole of the second tube and configured to discharge the process gas to the outside,
wherein the first tube has a plurality of exhaust holes penetrating a sidewall of the first tube, the plurality of exhaust holes comprise a main exhaust hole and a multi-exhaust hole region, the main exhaust hole extends in the vertical direction with a variable horizontal width, the multi-exhaust hole region comprises a plurality of auxiliary exhaust holes, and at least some of the plurality of auxiliary exhaust holes face the exhaust port.
